(19) United States
(12) Patent Application Publication
(10) Pub. No.: US 2025/0376758 A1
(43) Pub. Date: Dec. 11, 2025

(54) SELECTIVE DEPOSITION OF METAL-CONTAINING MATERIAL

(71) Applicant: ASM IP Holding B.V., Almere (NL)

(72) Inventors: Vincent Vandalon, Heverlee (BE); YongGyu Han, Leuven (BE); Marko Tuominen, Helsinki (FI); David Zanders, Leuven (BE)

(21) Appl. No.: 19/231,731

(22) Filed: Jun. 9, 2025

Related U.S. Application Data
(60) Provisional application No. 63/658,661, filed on Jun. 11, 2024.

(51) Int. Cl. C23C 16/04; C23C 16/455; H01L 21/02

(52) U.S. Cl. CPC C23C 16/04; C23C 16/45544; C23C 16/45553; H01L 21/02178; H01L 21/02192; H01L 21/0228; H01L 21/02299

(57) ABSTRACT

The disclosure relates to selective deposition methods for depositing metal-containing material on an electrically conductive surface of a substrate relative to a second surface of the substrate. The methods comprise providing the substrate comprising the electrically conductive surface and the second surface, contacting the substrate with an inhibitor reactant comprising silicon to passivate the second surface and contacting the substrate with an activator reactant comprising a silicon atom and a hydroxyl group to activate the electrically conductive surface. Thereafter, the method comprises depositing the metal-containing material on the electrically conductive surface by a cyclic deposition process. The disclosure further relates to semiconductor processing assemblies for performing the methods described herein.

### CROSS-REFERENCE TO RELATED APPLICATION(S)

This application claims the benefit of U.S. Provisional Application 63/658,661 filed on Jun. 11, 2024, the entire contents of which are incorporated herein by reference.

### FIELD

The present disclosure generally relates to methods and assemblies for processing semiconductor substrates. More particularly, the disclosure relates to methods and assemblies for selectively depositing a particular material on one surface of a semiconductor substrate relative to another surface of the same substrate.

### BACKGROUND

Semiconductor device fabrication processes generally use advanced vapor deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Various materials, such as metal oxides, metal nitrides, elemental metals and such materials combined with additional elements, may be used for various purposes in semiconductor devices. The ability to choose the deposition surface between dielectric materials and conductive materials, such as metals or conductive metal nitrides, can simplify device fabrication process flows, and thus allow the deposition of more sensitive materials, possibly more accurately, as the need for patterning and etching steps may be reduced.

Currently, well-controlled selective deposition process flows contain multiple steps, necessitating the use of several deposition chambers. Conversely, in simple process flows, the selectivity window is often too small for a reliable industrial-scale manufacturing process. There is thus need in the art for simple but robust selective deposition methods.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of selectively depositing a metal-containing material on an electrically conductive surface of a substrate relative to a second surface of the substrate. Embodiments of the current disclosure further relate to methods of fabricating semiconductor devices, and to substrate processing assemblies.

In one aspect, a selective deposition method for depositing metal-containing material on an electrically conductive surface of a substrate relative to a second surface of the substrate is disclosed. The method comprises providing the substrate comprising the electrically conductive surface and the second surface, contacting the substrate with an inhibitor reactant comprising silicon to passivate the second surface and contacting the substrate with an activator reactant comprising a silicon atom and a hydroxyl group to activate the electrically conductive surface. Thereafter, the method comprises depositing the metal-containing material on the electrically conductive surface by a cyclic deposition process.

In some embodiments, the metal-containing material comprises at least one of Al, Y, Zr, Hf, La, Ga, Ti and Ru. In some embodiments, the metal-containing material is selected from metal oxides and metal nitrides. In some embodiments, the metal-containing material is aluminum oxide, yttrium oxide or a combination thereof. In some embodiments, the metal-containing material is deposited as a layer.

In some embodiments, the electrically conductive surface is selected from elemental metals and conductive metal nitrides. In some embodiments, the conductive surface is an elemental metal surface. In some embodiments, the conductive surface is an elemental metal surface selected from Cu, Co, W, Ru, Al, Ta and Mo. In some embodiments, the electrically conductive surface is a conductive metal nitride surface. In some embodiments, the electrically conductive surface is selected from TaN, TiN, WN, MoN.

In some embodiments, the second surface is a dielectric surface. In some embodiments, the second surface is an insulating surface. In some embodiments, the second surface is a silicon-comprising surface. In some embodiments, the second surface is selected from SiO₂, SiN, SiOC, SiON, SiOCN, SiGe and combinations thereof.

In some embodiments, the inhibitor reactant comprises a Si—N bond or a Si-halogen bond. In some embodiments, the inhibitor reactant has a formula SiR₃NR′₂, wherein each R is independently selected from C1 to C5 alkyls and alkoxides, and each R′ is independently selected from C1 to C7 alkyls.

In some embodiments, the inhibitor reactant is selected from a group consisting of N-(trimethylsilyl)dimethylamine, 1-(triisopropylsilyl)pyrrole, 1-(trimethylsilyl)imidazole, 1,1,1-trimethoxy-N,N-dimethylsilanamine, bis(dimethylamino)dimethylsilane, bis(dimethylamino)diethylsilane and chlorotrimethylsilane.

In some embodiments, the activator reactant comprises a silicon-hydroxyl (Si—OH) bond. In some embodiments, the activator reactant is a silanol comprising at least one alkoxy substituent attached to the silanol silicon atom. In some embodiments, the activator reactant comprises at least two alkoxy substituents attached to the silanol silicon atom. In some embodiments, the activator reactant comprises one alkoxy substituent attached to the silanol silicon atom. In some embodiments, the activator reactant comprises two alkoxy substituents attached to the silanol silicon atom. In some embodiments, the activator reactant comprises three alkoxy substituents attached to the silanol silicon atom. In some embodiments, the activator reactant is selected from a group consisting of trimethoxysilanol, triethoxysilanol, tripropoxysilanol, tris(sec-butoxy)silanol, tris(tert-butoxy)silanol and tris(tert-pentoxy)silanol.

In some embodiments, the metal-containing material is deposited by an ALD process. In some embodiments, the cyclic deposition process for depositing a metal-containing material comprises contacting the substrate with a metal precursor and a second material precursor alternatively and sequentially. In some embodiments, the metal precursor comprises a ligand selected from alkyl ligands, alkoxy ligands, amino ligand, amidinato ligands, cyclopentadienyl ligands, β-diketonate ligands, halogen ligands and guanidinato ligands. In some embodiments, the metal precursor is a heteroleptic precursor.

In some embodiments, the second material precursor is selected from oxygen precursors and nitrogen precursors. In some embodiments, the second material precursor is an oxygen precursor. In some embodiments, the oxygen precursor is selected from a group consisting of ozone (O₃), molecular oxygen (O₂), oxygen atoms (O), an oxygen plasma, oxygen ions, oxygen radicals, oxygen excited species, water (H₂O), and hydrogen peroxide (H₂O₂). In some embodiments, the oxygen precursor is molecular oxygen (O₂). In some embodiments, the oxygen precursor is ozone. In some embodiments, the oxygen precursor is hydrogen peroxide. In some embodiments, the oxygen precursor is water. In some embodiment, the oxygen precursor comprises a hydroxyl group. In some embodiments, the oxygen precursor is an alcohol.

In some embodiments, the second material precursor is a nitrogen precursor. In some embodiments, the nitrogen precursor is selected from a group consisting of molecular nitrogen (N₂), ammonia (NH₃), hydrazine (NH₂NH₂) and a hydrazine derivative, such as tert-butylhydrazine.

In another aspect, a substrate processing assembly is disclosed. The assembly comprises a first reaction chamber and a second reaction chamber, each constructed and arranged to hold a substrate comprising an electrically conductive surface and a second surface. The substrate processing assembly further comprises a substrate transfer arrangement for moving the substrate from first reaction chamber to the second reaction chamber, a first reactant vessel constructed and arranged to hold an inhibitor reactant comprising silicon, a second reactant vessel constructed and arranged to hold an activator reactant comprising a silanol, a third reactant vessel constructed and arranged to hold a metal precursor and a fourth reactant vessel constructed and arranged to hold a second material precursor. The substrate processing assembly also comprises a precursor injector system constructed and arranged to provide the inhibitor reactant and the activator reactant from the first reactant vessel and the second reactant vessel, respectively, to the first reaction chamber in a vapor phase; and the metal precursor and the second material precursor from the third reactant vessel and the fourth reactant vessel, respectively, to the second reaction chamber in a vapor phase. In some embodiments, the substrate processing assembly comprises a controller configured to control the flow of the inhibitor reactant and the activator reactant into the first reaction chamber, and the flow of the metal precursor and second material precursor into the second reaction chamber for executing the method according to the current disclosure, thereby selectively depositing a metal-containing material on the electrically conductive surface of the substrate.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings:

FIG. 1 is a block diagram of exemplary embodiments of a method according to the current disclosure.

FIG. 2 is a block diagram of exemplary embodiments of a cyclic deposition of a metal-containing material according to the current disclosure.

FIG. 3 is an electron micrograph of a metal-containing material layer deposited according to the current disclosure.

FIG. 4 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

### Substrate

The current disclosure relates to selective deposition methods for depositing metal-containing material on an electrically conductive surface of a substrate relative to a second surface of the substrate. The deposition method according to the current disclosure comprises providing a substrate. The substrate is provided in a reaction chamber. In embodiments of the current disclosure, the substrate may be provided in one, two or more reaction chambers during the method according to the current disclosure. Without limiting the generality of the current disclosure, some phases of the current method may be incompatible with other phases. Therefore, the substrate may be moved from one chamber to another, or from one deposition station of a reaction chamber to another during the method.

The substrate according to the current disclosure may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device. A substate according to the current disclosure comprises an electrically conductive surface and a second surface. The electrically conductive surface and the second surface have different material properties, allowing for the selective deposition of a metal-containing material on the electrically conductive surface.

In some embodiments, the electrically conductive surface is selected from elemental metals and conductive metal nitrides. In some embodiments, the conductive surface is an elemental metal surface. An elemental metal surface according to the current disclosure consists essentially of or consists of elemental metal, i.e. the oxidation state of the majority of the metal on the metal surface is zero. Additionally, in an elemental metal surface, other elements, such as carbon, nitrogen and oxygen are substantially absent. However, an elemental metal surface may comprise an acceptable amount of impurities. In some embodiments, the conductive surface is an elemental metal surface selected from Cu, Co, W, Ru, Al, Ta and Mo. In some embodiments, the conductive surface is an elemental Cu surface. In some embodiments, the conductive surface is an elemental Co surface. In some embodiments, the conductive surface is an elemental W surface. In some embodiments, the conductive surface is an elemental Ru surface. In some embodiments, the conductive surface is an elemental Al surface. In some embodiments, the conductive surface is an elemental Ta surface. In some embodiments, the conductive surface is an elemental Mo surface.

In some embodiments, the electrically conductive surface is a conductive metal nitride surface. In the current disclosure, a metal nitride is a surface consisting essentially, or consisting of one or more metals and nitrogen. A metal nitride surface may also comprise an acceptable amount of impurities, such as carbon. In some embodiments, the electrically conductive surface is selected from TaN, TiN, WN, MoN. In some embodiments, the conductive surface is a TaN surface. In some embodiments, the conductive surface is a TiN surface. In some embodiments, the conductive surface is a WN surface. In some embodiments, the conductive surface is a MoN surface.

In some embodiments, a conductive surface according to the current disclosure is a silicon-containing conductive surface, such as SiGe surface or SiGeB surface. In some embodiments, a conductive surface according to the current disclosure is a SiGe surface or a SiGeB surface. In embodiments, in which the electrically conductive surface comprises SiGe, the portion of Ge needs to be sufficiently high for achieving the deposition according to the current disclosure. The proportion of Ge in the SiGe or SiGeB material may be higher than about 10 at-%, such as at least about 15 at-%, or at least about 35%, or at least about 50 at-%, such as about 40 at-% or about 60 at-%.

In some embodiments, the second surface is a dielectric surface. The term dielectric is used in the description herein for the sake of simplicity in distinguishing from electrically conductive surfaces. It will be understood by those skilled in the art that not all non-conducting surfaces are dielectric surfaces. Selective deposition processes taught herein can deposit on electrically conductive surfaces with minimal deposition on adjacent dielectric surfaces. In some embodiments, the second surface is an insulating surface.

In some embodiments, the second surface is a silicon-comprising surface. In some embodiments, the second surface is selected from SiO₂, SiN, SiOC, SiON, SiOCN, SiGe and combinations thereof.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

Embodiments of the current disclosure are performed in one or more reaction chambers. When a substrate is provided in a reaction chamber, the substrate is in a space where the deposition conditions can be controlled. The reaction chamber may be a reaction chamber or a deposition chamber of a single wafer reactor. Alternatively, the reaction chamber may be a batch reaction chamber. The reaction chamber can form part of a substrate processing assembly for manufacturing semiconductor devices. The substrate processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, contacting the substrate with the inhibitor reactant and with the activator reactant are done in one reaction chamber, and the metal-containing material is deposited in a second reaction chamber. In some embodiments, the substrate is contacted by the inhibitor reactant and the activator reactant in one reaction chamber, and the cyclic deposition process to deposit metal-containing material on the electrically conductive surface is performed in a second reaction chamber. In some embodiments, the substrate is contacted by the inhibitor reactant and the activator reactant in separate reaction chambers, and the cyclic deposition process to deposit metal-containing material on the electrically conductive surface is performed in a further reaction chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of an atomic layer deposition (ALD) assembly. The reaction chamber can form part of a chemical vapor deposition (CVD) assembly. The substrate processing assembly may be an ALD or a CVD deposition assembly. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

### Inhibitor Reactant

In the current method, substrate is contacted with an inhibitor reactant comprising silicon to passivate the second surface.

In some embodiments, the inhibitor reactant comprises a Si—N bond or a Si-halogen bond. In some embodiments, the inhibitor reactant has a formula SiR₃NR′₂, wherein each R is independently selected from C1 to C6 hydrocarbons and alkoxides, and each R′ is independently selected from C1 to C7 alkyls. In some embodiments, at least one R is an alkyl. In some embodiments, each R is an alkyl. In some embodiments, at least one R is an aromatic hydrocarbon. In some embodiments, all R are an aromatic hydrocarbon. In some embodiments, the aromatic hydrocarbon comprises an alkyl substituent.

In some embodiments, the inhibitor reactant is selected from a group consisting of Si(Me)₃N(Me)₂, Si(Me)₃N(Et)₂, Si(Me)₃N(Me)(Et), Si(Et)₃N(Me)₂, Si(Et)₃N(Et)₂, Si(Et)₃N(Me)(Et), Si(Pr)₃N(Me)₂, Si(Pr)₃N(Et)₂, Si(Pr)₃N(Me)(Et), Si(Et)₂(Me)N(Me)₂, Si(Et)₂(Me)N(Et)₂, Si(Et)₂(Me)N(Me)(Et), Si(Et)(Me)₂N(Me)₂, Si(Et)(Me)₂N(Et)₂, Si(Et)(Me)₂N(Me)(Et), Si(OMe)₃N(Me)₂, Si(OMe)₃N(Et)₂, Si(OMe)₃N(Me)(Et), Si(OEt)₃N(Me)₂, Si(OEt)₃N(Et)₂, Si(OEt)₃N(Me)(Et), Si(OPr)₃N(Me)₂, Si(OPr)₃N(Et)₂, Si(OPr)₃N(Me)(Et), Si(Me)(OMe)₂N(Me)₂, Si(Me)(OMe)₂N(Et)₂, Si(Me)(OMe)₂N(Me)(Et), Si(Me)(OEt)₂N(Me)₂, Si(Me)(OEt)₂N(Et)₂, Si(Me)(OEt)₂N(Me)(Et), Si(Me)(OPr)₂N(Me)₂, Si(Me)(OPr)₂N(Et)₂, Si(Me)(OPr)₂N(Me)(Et), Si(Me)₂(OMe)N(Me)₂, Si(Me)₂(OMe)N(Et)₂, Si(Me)₂(OMe)N(Me)(Et), Si(Me)₂(OEt)N(Me)₂, Si(Me)₂(OEt)N(Et)₂, Si(Me)₂(OEt)N(Me)(Et), Si(Me)₂(OPr)N(Me)₂, Si(Me)₂(OPr)N(Et)₂, Si(Me)₂(OPr)N(Me)(Et), Si(Et)(OMe)₂N(Me)₂, Si(Et)(OMe)₂N(Et)₂, Si(Et)(OMe)₂N(Me)(Et), Si(Et)(OEt)₂N(Me)₂, Si(Et)(OEt)₂N(Et)₂, Si(Et)(OEt)₂N(Me)(Et), Si(Et)(OPr)₂N(Me)₂, Si(Et)(OPr)₂N(Et)₂, Si(Et)(OPr)₂N(Me)(Et), Si(Et)₂(OMe)N(Me)₂, Si(Et)₂(OMe)N(Et)₂, Si(Et)₂(OMe)N(Me)(Et), Si(Et)₂(OEt)N(Me)₂, Si(Et)₂(OEt)N(Et)₂, Si(Et)₂(OEt)N(Me)(Et), Si(Et)₂(OPr)N(Me)₂, Si(Et)₂(OPr)N(Et)₂, Si(Et)₂(OPr)N(Me)(Et), Si(OEt)₂(OMe)N(Me)₂, Si(OEt)₂(OMe)N(Et)₂, Si(OEt)₂(OMe)N(Me)(Et), Si(OEt)(OMe)₂N(Me)₂, Si(OEt)(OMe)₂N(Et)₂, Si(OEt)(OMe)₂N(Me)(Et), SiMe₂(NMe₂)₂, SiMe₂(NEt₂)₂, SiMe₂(N(Me)(Et))₂, SiMe₂(NPr₂)₂, SiMe₂(NⁱPr₂)₂, SiEt₂(NMe₂)₂, SiEt₂(NEt₂)₂, SiEt₂(N(Me)(Et))₂, SiEt₂(NPr₂)₂, SiEt₂(NⁱPr₂)₂, SiPr₂(NMe₂)₂, SiPr₂(NEt₂)₂, SiPr₂(N(Me)(Et))₂, SiPr₂(NPr₂)₂, SiPr₂(NⁱPr₂)₂, Si(Me)₃Pyr, Si(Et)₃Pyr, Si(ⁱPr)₃Pyr, Si(Pr)₃Pyr, Si(ⁿBu)₃Pyr, Si(^{s}Bu)₃Pyr, Si(ⁱBu)₃Pyr, Si(^{t}Bu)₃Pyr, Si(Me)₃Im, Si(Et)₃Im, Si(ᵢPr)₃Im, Si(Pr)₃Im, Si(ⁿBu)₃Im, Si(^{s}Bu)₃Im, Si(ᵢBu)₃Im, Si(^{t}Bu)₃Im, Si(Ph)₃NMe₂, Si(Ph)₃NEt₂, SiClMe₃, SiCl₂Me₂, SiCl₃Me, SiClEt₃, SiCl₂Et₂, SiCl₃Et, SiClPr₃, SiCl₂Pr₂, SiCl₃Pr, SiClⁱPr₃, SiCl₂¹Pr₂, SiCl₃ⁱPr, SiCl^{t}Bu₃, SiCl₂^{t}Bu₂, SiCl₃^{t}Bu, SiBrMe₃, SiBr₂Me₂, SiBr₃Me, SiBrEt₃, SiBr₂Et₂, SiBr₃Et, SiBrPr₃, SiBr₂Pr₂, SiBr₃Pr, SiBrⁱPr₃, SiBr₂ⁱPr₂, SiBr₃ⁱPr, SiBr^{t}Bu₃, SiBr₂^{t}Bu₂, SiBr₃^{t}Bu, SiIMe₃, SiI₂Me₂, SiI₃Me, SiIEt₃, SiI₂Et₂, SiI₃Et, SiIPr₃, SiI₂Pr₂, SiI₃Pr, SiIⁱPr₃, SiI₂ⁱPr₂, SiI₃ⁱPr, SiI^{t}Bu₃, SiI₂^{t}Bu₂, SiI₃^{t}Bu, wherein Me stands for methyl, Et for ethyl, OMe for methoxy, OEt for ethoxy, Pr for n-propyl, ⁱPr for isopropyl, ⁿBu for n-butyl, ^{s}Bu for sec-butyl, ⁱBu for isobutyl, ^{t}Bu for tert-butyl, Pyr for pyrrole, Im for imidazole, Ph for phenyl, and wherein pyrrole or imidazole, respectively, is attached to the silicon atom through nitrogen and OMe or OEt, respectively, through the alkoxy oxygen.

In some embodiments, the inhibitor reactant is selected from a group consisting of N-(trimethylsilyl)dimethylamine, 1-(triisopropylsilyl)pyrrole, 1-(trimethylsilyl)imidazole, 1,1,1-trimethoxy-N,N-dimethylsilanamine, bis(dimethylamino)dimethylsilane, bis(dimethylamino)diethylsilane and chlorotrimethylsilane. In some embodiments, the electrically conductive surface is an elemental cobalt surface, and the inhibitor agent is not bis(dimethylamino)dimethylsilane.

The inhibitor reactant according to the current disclosure may comprise more than one silicon atom. For example, the inhibitor reactant may comprise two silicon atoms. Each of the two silicon atoms may be attached to a nitrogen atom. Each of the silicon atoms may be attached to an alkylamine group, such as a dialkylamine group. Without limiting the current disclosure to any specific theory, the additional number of silicon atoms and alkylamine groups may improve the passivation properties of the inhibitor reactant.

In the methods according to the current disclosure, the substrate is contacted with an inhibitor reactant in a gas phase. The inhibitor reactant is provided into a reaction chamber, which may have a reduced pressure. In some embodiments, the temperature at which the inhibitor reactant is provided is from about 150° C. to about 350° C., such as from about 200° C. to about 300° C., for example from about 200° C. to 250° C. or from about 250° C. to about 300° C.

In some embodiments, the substrate is contacted with the inhibitor reactant at a reduced pressure. In some embodiments, the pressure during the method according to the current disclosure is less than about 200 Torr, or a pressure within the reaction chamber during the deposition process is between about 0.1 Torr and about 200 Torr, or between about 0.1 Torr and about 150 Torr, or between about 0.1 Torr and about 100 Torr, or between about 0.1 Torr and about 80 Torr, or between about 0.1 Torr and about 50 Torr, or between about 0.1 Torr and about 20 Torr. In some embodiments, a pressure during the deposition process is less than about 10 Torr, or less than about 6 Torr, or less than about 3 Torr, or about 2 Torr or less. A pressure in a reaction chamber may be selected independently for different process steps. In some embodiments, at least two different pressures are used. In some embodiments, a first pressure is used during contacting the substrate with the inhibitor reactant, and a second pressure is used during contacting the substrate with the activator reactant. In some embodiments, a third pressure is used when depositing the metal-containing material on the first surface of the substrate.

The duration of contacting the substrate with the inhibitor reactant may vary. In some embodiments, the inhibitor reactant is provided in pulses. In some embodiments, the duration of contacting the substrate with the inhibitor reactant, by providing the inhibitor reactant continuously or in pulses, is from about 5 seconds to about 180 seconds, such as from about 10 seconds to about 180 seconds, or from about 30 seconds to about 180 seconds, or from about 45 seconds to about 180 seconds, or from about 60 seconds to about 180 seconds, or from about 120 seconds to about 180 seconds. In some embodiments, the duration of contacting the substrate with the inhibitor reactant, by providing the inhibitor reactant continuously or in pulses, is from about 5 seconds to about 120 seconds, such as from about 5 seconds to about 90 seconds, or from about 5 seconds to about 60 seconds, or from about 5 seconds to about 45 seconds, or from about 5 seconds to about 30 seconds, or from about 5 seconds to about 15 seconds. For example, the duration of contacting the substrate with the inhibitor reactant may be about 10 seconds, about 25 seconds, about 30 seconds, about 40 seconds or about 60 seconds.

Without limiting the current disclosure to any specific theory, the inhibitor reactant may silylate the substrate surface. The silicon atom of the inhibitor reactant may become attached to the second surface, such as a dielectric surface, for example a silicon-containing dielectric surface.

Contacting the substrate with the inhibitor reactant may be followed by a purge. In case the substrate is contacted with the inhibitor reactant in pulses, the reaction chamber may be purged between consecutive inhibitor reactant pulses.

### Activator Reactant

In the methods according to the current disclosure, the substrate is contacted with an activator reactant comprising a silicon atom and a hydroxyl group to activate the electrically conductive surface. The substrate is contacted with an activator reactant after the substrate has been contacted with the inhibitor reactant. In some embodiments, the substrate is contacted with a vapor-phase activator reactant. Thus, the activator reactant is gaseous when it contacts the substrate. In some applications, such as spin-coating, a liquid activator reactant may be used. Thereafter, the method comprises depositing the metal-containing material on the electrically conductive surface by a cyclic deposition process.

The activator reactant comprises a silicon atom and a hydroxyl group. In some embodiments, the activator reactant is a silanol having at least one alkoxy group bonded to the silicon atom. Thus, the activator reactant according to the current disclosure comprises a molecule having a hydroxyl group bonded to a silicon atom (Si—OH). The molecule may contain one or more silicon atoms, and one or more of the silicon atoms may be bonded to a hydroxyl group. In some embodiments, the activator reactant comprises one silicon atom. In some embodiments, the activator reactant comprises one silicon atom and the silicon atom is bonded to one hydroxyl group. In some embodiments, the activator reactant comprises one silicon atom and the silicon atom is bonded to two hydroxyl groups. In some embodiments, the activator reactant comprises one silicon atom and the silicon atom is bonded to three hydroxyl groups.

In some embodiments, the activator reactant comprises one silicon atom and the silicon atom is bonded to one hydroxyl group and three alkoxy groups (Si(OR)₃OH). In some embodiments, the activator reactant comprises one silicon atom and the silicon atom is bonded to one hydroxyl group, two alkoxy groups and one alkyl group (SiR(OR)₂OH). In some embodiments, the activator reactant comprises one silicon atom and the silicon atom is bonded to one hydroxyl group, one alkoxy group and two alkyl groups (SiR₂(OR)OH).

In some embodiments, the activator reactant comprises one silicon atom and the silicon atom is bonded to two hydroxyl groups. In some embodiments, the activator reactant comprises one silicon atom and the silicon atom is bonded to two hydroxyl groups and two alkoxy groups (Si(OH)₂(OR)₂). In some embodiments, the activator reactant comprises one silicon atom and the silicon atom is bonded to two hydroxyl groups, to one alkyl group and to one alkoxy group (Si(OH)₂R(OR)).

In some embodiments, the activator reactant comprises one silicon atom and the silicon atom is bonded to three hydroxyl groups. In some embodiments, the activator reactant comprises one silicon atom and the silicon atom is bonded to three hydroxyl groups and one alkoxy group (Si(OR)(OH)₃).

In some embodiments, the activator reactant comprises two silicon atoms. In some embodiments, the activator reactant comprises two silicon atoms and each of the silicon atoms is bonded to a hydroxyl group. In some embodiments, the activator reactant comprises two silicon atoms and each of the silicon atoms is bonded to one hydroxyl group. In some embodiments, the activator reactant comprises two silicon atoms and one of the silicon atoms is bonded to one hydroxyl group. In some embodiments, the activator reactant comprises two silicon atoms and one of the silicon atoms is bonded to two hydroxyl groups. In some embodiments, the activator reactant comprises three silicon atoms. In some embodiments, the activator reactant comprises three silicon atoms and one of the silicon atoms is bonded to a hydroxyl group. In some embodiments, the activator reactant comprises three silicon atoms and two of the silicon atoms is bonded to a hydroxyl group. In some embodiments, the activator reactant comprises three silicon atoms and each of the silicon atoms is bonded to a hydroxyl group. Each of the silicon atoms may be bonded to one or two hydroxyl groups.

The activator reactant may further contain an alkyl group. An alkyl group according to the current disclosure is a C1 to C7 alkyl, or a C1 to C5 alkyl, and it may be linear, branched or cyclic. For example, the one or more alkyl groups may be selected from a group consisting of methyl, ethyl, n-propyl, isopropyl, n-butyl, isobutyl, sec-butyl, tert-butyl, n-pentyl, 1,1-dimethylpropyl, 3-methylbutyl, 1-methylbutyl, 2,2-dimethylpropyl. 1-ethylpropyl, 1,2-dimethylpropyl, 2-methylbutyl, n-hexyl, 1-methylpentyl, 2-methylpentyl, 3-methylpentyl, 4-methylpentyl, 1,1-dimethylbutyl, 1,2-dimethylbutyl, 1,3-dimethylbutyl, 2,2-dimethylbutyl, 3,3-dimethylbutyl, 1-ethylbutyl and 2-ethylbutyl.

In some embodiments, the activator reactant comprises an alkoxy group. In some embodiments, the alkoxy group is bonded to a silicon atom through the alkoxy oxygen. In some embodiments, the activator reactant comprises one alkoxy group. In some embodiments, the activator reactant comprises two alkoxy groups. In some embodiments, the activator reactant comprises three alkoxy groups. In some embodiments, the activator reactant comprises four alkoxy groups. An alkoxy group can be linear or branched. An alkoxy group may be a C1 to C5 alkoxy group. In some embodiments, each of the alkoxy groups in the activator reactant is independently selected from a group consisting of methoxy, ethoxy, n-propoxy, isopropoxy, n-butoxy, isobutoxy, sec-butoxy, tert-butoxy, n-pentoxy, 1,1-dimethylpropoxy, 3-methylbutoxy, 1-methylbutoxy, 2,2-dimethylpropoxy, 1-ethylpropoxy, 1,2-dimethylpropoxy and 2-methylbutoxy.

In some embodiments, the activator reactant comprises one silicon atom bonded to two alkyl groups, one hydroxyl group and one alkoxide group. In some embodiments, the activator reactant comprises one silicon atom bonded to one alkyl group, one hydroxyl group and two alkoxide groups. In some embodiments, the activator reactant comprises one silicon atom bonded to one alkyl group, two hydroxyl groups and one alkoxide groups. In some embodiments, the alkoxide group is branched. In some embodiments, the activator reactant comprises one silicon atom, one C1 to C3 alkyl group, one hydroxyl group and two branched alkoxy groups. In some embodiments, the activator reactant comprises one silicon atom, one C1 to C2 alkyl group, one hydroxyl group and two branched alkoxy groups. In some embodiments, the activator reactant comprises one silicon atom, methyl, one hydroxyl group and two branched alkoxy groups. In some embodiments, the activator reactant comprises one silicon atom, methyl, one hydroxyl group and two branched C5 alkoxy groups.

In some embodiments, the activator reactant is represented by a formula SiₐRₓ(OH)_{y}(OR′)_{z}, wherein a is 1, 2 or 3, each x, y and z is at least 1, z+y+z=a+2, and each R and R′ is independently selected from linear and branched C1 to C6 alkyls. In some embodiments, the activator reactant is selected from Si(OH)₂R(OR′), Si(OH)R₂(OR′), Si(OH)R(OR′)₂, Si₂(OH)₂R₂(OR′)₂, Si₂(OH)R₂(OR′)₂. In some embodiments, each R is methyl or ethyl. In some embodiments, each R and R′ is independently selected from linear and branched C1 to C5 alkyls. In some embodiments, R is selected from C1 to C5 alkyls, and R′ is selected from C1 to C3 alkyls. In some embodiments, R′ is branched. In some embodiments, R′ is selected from, isopropyl, sec-butyl, tert-butyl, 1,1-dimethylpropyl, 2,2-dimethylpropyl, 1-methylbutyl, 3-methylbutyl, 3-pentyl, 1,2-dimethylpropyl and 2-methylbutyl. In some embodiments, z is 2, and each R′ is identical.

In some embodiments, the activator reactant is selected from a group consisting of Si(OH)CH₃(OCH(CH₃)₂)₂, Si(OH)₂CH₃(OCH(CH₃)₂), Si(OH)(CH₃)₂(OCH(CH₃)₂), Si(OH)CH₃(OC(CH₃)₃)₂, Si(OH)₂CH₃(OC(CH₃)₃), Si(OH)(CH₃)₂(OC(CH₃)₃), Si(OH)CH₂CH₃(OC(CH₃)₃)₂, Si(OH)₂CH₂CH₃(OC(CH₃)₃), Si(OH)(CH₂CH₃)₂(OC(CH₃)₃), Si(OH)CH₃(OC(CH₂CH₃)₃)₂, Si(OH)₂CH₃(OC(CH₂CH₃)₃) and Si(OH)(CH₃)₂(OC(CH₂CH₃)₃).

In some embodiments, the activator reactant comprises a silicon-hydroxyl (Si—OH) bond. In some embodiments, the activator reactant is a silanol comprising at least one alkoxy substituent attached to the silanol silicon atom. In some embodiments, the activator reactant comprises at least two alkoxy substituents attached to the silanol silicon atom. In some embodiments, the activator reactant comprises one alkoxy substituent attached to the silanol silicon atom. In some embodiments, the activator reactant comprises two alkoxy substituents attached to the silanol silicon atom. In some embodiments, the activator reactant comprises three alkoxy substituents attached to the silanol silicon atom. In some embodiments, the activator reactant is selected from a group consisting of trimethoxysilanol, triethoxysilanol, tripropoxysilanol, tris(sec-butoxy)silanol, tris(tert-butoxy)silanol and tris(tert-pentoxy)silanol.

In the methods according to the current disclosure, the activator reactant selectively activates the electrically conductive surface. Without limiting the current disclosure to any specific theory, the activator reactant may have higher affinity to metal or metallic surfaces, such as metal nitride surfaces, than for other surfaces. through a specific component. As a result of the activation by the activator reactant, the electrically conductive surface may comprise Si—OH terminations, which, may allow or improve the chemisorption of a metal precursor on the electrically conductive surface. In some embodiments, the electrically conductive surface is an elemental cobalt surface, and the activator agent is not bis(tert-pentoxy)methylsilanol.

In some embodiments, the substrate is contacted with the activator reactant at a temperature from about 150° C. to about 400° C., such as from about 200° C. to about 350° C., for example from about 200° C. to 300° C. or from about 250° C. to about 350° C. In some embodiments, the substrate is contacted with the activator reactant at a temperature of about 225° C. or about 250° C. or about 300° C. or about 325° C. or about 350° C.

The duration of contacting the substrate with the activator reactant may vary. In some embodiments, the activator reactant is provided in pulses. In some embodiments, the duration of contacting the substrate with the activator reactant, by providing the activator reactant continuously or in pulses, is from about 5 seconds to about 500 seconds, such as from about 10 seconds to about 500 seconds, or from about 30 seconds to about 500 seconds, or from about 45 seconds to about 500 seconds, or from about 60 seconds to about 500 seconds, or from about 120 seconds to about 500 seconds. In some embodiments, the duration of contacting the substrate with the activator reactant, by providing the activator reactant continuously or in pulses, is from about 5 seconds to about 300 seconds, such as from about 5 seconds to about 240 seconds, or from about 5 seconds to about 180 seconds, or from about 5 seconds to about 120 seconds, or from about 5 seconds to about 60 seconds, or from about 5 seconds to about 30 seconds. For example, the duration of contacting the substrate with the activator reactant may be about 15 seconds, about 25 seconds, about 45 seconds, about 60 seconds or about 90 seconds.

In some embodiments, the substrate is contacted with the activator reactant at a reduced pressure. In some embodiments, the substrate is contacted with the activator reactant at the same pressure as the inhibitor reactant. In some embodiments, the substrate is contacted with the activator reactant at a different pressure than the inhibitor reactant. In some embodiments, the substrate is contacted with the activator reactant at a lower pressure than the inhibitor reactant.

In some embodiments, the pressure during contacting the substrate with the activator reactant is less than about 50 Torr, or a pressure within the reaction chamber during the deposition process is between about 0.1 Torr and about 50 Torr, or between about 0.1 Torr and about 20 Torr, or between about 0.1 Torr and about 10 Torr. In some embodiments, a pressure during contacting the substrate with the activator reactant is less than about 10 Torr, or less than about 6 Torr, or less than about 3 Torr, or about 2 Torr or less.

Contacting the substrate with the activator reactant may be followed by a purge. In case the substrate is contacted with the activator reactant in pulses, the reaction chamber may be purged between consecutive activator reactant pulses.

### Deposition of Metal-Containing Material

In some embodiments, the metal-containing material is deposited by an ALD process. In some embodiments, the cyclic deposition process for selectively depositing a metal-containing material comprises contacting the substrate with a metal precursor and a second material precursor alternatively and sequentially.

The current disclosure relates to a selective deposition process. Selectivity can be given as a percentage calculated by [(deposition on the electrically conductive surface)−(deposition on second surface)]/(deposition on the electrically conductive surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

Selectivity in a cyclic deposition process may further be characterized by a selectivity window. By a selectivity window is herein meant the difference in the cycle numbers after which growth of a target material, such as a metal-containing material according to the current disclosure, is observed on the first surface and on the second surface, respectively. The more selective the process, the larger the difference in cycle numbers between the two surfaces is.

In some embodiments, deposition only occurs on the electrically conductive surface and does not occur on the second surface. In some embodiments, deposition on the electrically conductive surface of the substrate relative to the second surface of the substrate is at least about 80% selective, which may be selective enough for some particular applications. In some embodiments the deposition on the electrically conductive surface of the substrate relative to the second surface of the substrate is at least about 50% selective, which may be selective enough for some particular applications. In some embodiments the deposition on the electrically conductive surface of the substrate relative to the second surface of the substrate is at least about 10% selective, which may be selective enough for some particular applications.

Selectivity may be achieved to a certain thickness of deposited material, and be lost in case deposition is continued beyond a process-specific threshold. Thus, it may be possible to deposit a layer of metal-containing material, for example, about 0.3 nm, about 0.5 nm, about 1 nm, about 2 nm, about 3 nm, about 5 nm or about 6 nm before selectivity is lost. If thicker material layers are desired, the contrast between the electrically conductive surface and the second surface may be enhanced though passivating the second surface. Alternatively or in addition, intermittent etch-back phase using, for example plasma, such as hydrogen plasma, may be used to keep selectivity.

In some embodiments, the cyclic deposition process according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD.

In some embodiments, the metal-containing material is aluminum oxide, yttrium oxide or a combination thereof. In some embodiments, the metal-containing material is deposited as a layer. As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, the metal-containing material is deposited as a layer. In some embodiments, the layer is substantially continuous. In some embodiments, the layer is substantially pinhole-free. In some embodiments, the thickness of the metal-containing material layer is at least 10 Å. In some embodiments, the thickness of the metal-containing material layer is at least 20 Å. In some embodiments, the thickness of the metal-containing material layer is at least 30 Å. In some embodiments, the thickness of the metal-containing material layer is from about 10 Å to about 60 Å, such as from about 25 Å toa about 40 Å, for example about 35 Å, or about 40 Å or about 50 Å.

The metal-containing material according to the current disclosure is deposited by a cyclic deposition process. The cyclic deposition process comprises contacting the substrate with a vapor-phase metal precursor and a vapor-phase second material precursor. In some embodiments, the metal precursor and the second material precursor are provided into the reaction chamber in pulses. In some embodiments, the metal precursor and the second material precursor are provided into the reaction chamber alternately and sequentially. Providing a metal precursor pulse and a second material precursor pulse form a deposition cycle. A deposition cycle may further comprise purging the reaction chamber after the metal precursor pulse and/or after the second material precursor pulse. In some embodiments, the metal-containing material may contain additional elements, such as additional metals or semimetals. In such embodiments, a deposition cycle may comprise additional precursor pulses. Depending on the desired proportions of different elements in the metal-containing material, only some of the deposition cycles may comprise an additional precursor pulse.

Generally, in cyclic deposition processes according to the current disclosure, such as atomic layer deposition (ALD), during each cycle, a precursor, such as a metal precursor, is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant, such as the second material precursor, may be introduced into the reaction chamber for use in converting the chemisorbed precursor into the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a metal precursor into the reaction chamber. In some embodiments, the cyclic deposition process comprises purging the reaction chamber after providing a second material precursor into the reaction chamber. In some embodiments, the cyclic deposition process comprises purging the reaction chamber after providing a first precursor into the reaction chamber, and after providing second precursor into the reaction chamber and providing an optional further precursor into the reaction chamber. Without limiting the current disclosure to any specific theory, ALD may be characterized by self-limiting reactions and slower and more controllable material growth speed compared to CVD.

CVD-type processes may be characterized by vapor deposition which is not self-limiting. They typically involve gas-phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, CVD is a cyclic deposition process. Cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

The process according to the current disclosure may comprise one or more cyclic phases. In some embodiments, the process comprises or one or more continuous phases. In some embodiments, the inhibitor reactant and the activator reactant are provided into the reaction chamber continuously. In some embodiments, at least one of the inhibitor reactant and the activator reactant is provided into the reaction chamber continuously. In some embodiments, the deposition process comprises the continuous flow of at least one precursor or a reactant.

In some embodiments, the metal-containing material comprises at least one of Al, Y, Zr, Hf, La, Ga, Ti and Ru.

The metal precursor according to the current disclosure comprises the desired metal of the metal-containing material. In some embodiments, the metal of the metal-containing material is selected from a group consisting of aluminum (Al), yttrium (Y), zirconium (Zr), hafnium (Hf), lanthanum (La), gallium (Ga), titanium (Ti) and ruthenium (Ru).

In some embodiments, the metal-containing material comprises Al, and the metal precursors is an Al precursor. In some embodiments, the metal-containing material comprises Y, and the metal precursors is an Y precursor. In some embodiments, the metal-containing material comprises Zr, and the metal precursors is a Zr precursor. In some embodiments, the metal-containing material comprises Hf, and the metal precursors is a Hf precursor. In some embodiments, the metal-containing material comprises La, and the metal precursors is a La precursor. In some embodiments, the metal-containing material comprises Ga, and the metal precursors is a Ga precursor. In some embodiments, the metal-containing material comprises Ti, and the metal precursors is a Ti precursor. In some embodiments, the metal-containing material comprises Ru, and the metal precursors is a Ru precursor.

In some embodiments, the metal precursor comprises a ligand selected from alkyl ligands, alkoxy ligands, amino ligand, amidinato ligands, cyclopentadienyl ligands, β-diketonate ligands, halogen ligands and guanidinato ligands. In some embodiments, the metal precursor is a heteroleptic precursor.

In some embodiments, the metal precursor comprises at least one alkyl ligand, such as methyl, ethyl, n-propyl, isopropyl (ⁱPr), n-butyl (Bu), iso-butyl (ⁱBu), tert-butyl (^{t}Bu) sec-butyl (^{s}Bu), n-pentyl (Pc), 1,1-dimethylpropyl, 3-methylbutyl, 1-methylbutyl, 2,2-dimethylpropyl, 1-ethylpropyl, 1,2-dimethylpropyl or 2-methylbutyl. In some embodiments, the metal precursor comprises at least one alkoxy ligand, such as methoxy, ethoxy, n-propoxy, isopropoxy or tert-butoxy, sec-butoxy, 1-methoxy-2-methyl-2-propoxy (mmp), dimethylaminoethoxy (dmae), dimethylamino-2-propoxy (dmap) or 1-dimethylamino2-methyl-2-propoxy (dmamp). In some embodiments, the metal precursor comprises at least one amino ligand, such as isopropylamino, dialkylamino, such as dimethylamino, diethylamino, ethylmethylamino, diisopropylamino or bis(trimethylsilyl)amido. In some embodiments, the metal precursor comprises at least one β-diketonate ligand, such as 2,2,6,6-tetramethylheptane-3,5-dionate (thd), acetylacetonate (acac) or 1,1,1,5,5,5-hexafluoroacetylacetonate (hfac). In some embodiments, the metal precursor comprises at least one halogen ligand, such as Cl, I, Br or F. In some embodiments, the metal precursor comprises at least one acetamidinato ligand, such as N,N′-diisopropyl-acetamidinate. In some embodiments, the metal precursor comprises at least one formamidinato ligand, such as N,N′-diisopropyl-formamidinate. In some embodiments, the metal precursor comprises at least one guanidinato ligand, such as N,N′-diisopropyl-2-dimethylamido-guanidinate.

In some embodiments, the metal precursor comprises an at least one amidinato ligand, such as ⁱPrAMD, ⁱPr₂AMD, MeAMD, ⁱPrFMD or ^{t}Bu₂FMD, wherein AMD stands for acetamidinato and FMD for formamidinato. In some embodiments, the amidinato ligand comprises an acetamidinato ligand. In some embodiments, the acetamidinato ligand is an alkylacetamidinato ligand. In some embodiments, the alkylacetamidinato ligand is a dialkylacetamidinato ligand. In some embodiments, the one or two alkyl groups of the alkylacetamidinato ligand are selected from a group consisting of methyl, ethyl, n-propyl, isopropyl, n-butyl, tert-butyl and sec-butyl. In some embodiments, the acetamidinato group comprises two identical alkyl groups.

In some embodiments, the metal precursor comprises at least one, optionally substituted, cyclopentadienyl ligand, such as cyclopentadienyl, methylcyclopentadienyl, pentamethylcyclopentadienyl, ethylcyclopentadienyl, isopropylcyclopentadienyl, butylcyclopentadienyl or sec-butylcyclopentadienyl. In some embodiments, the cyclopentadienyl ligand comprises at least one C1 to C5 alkyl substituent. In some embodiments, the alkyl substituent is selected from a group consisting of methyl, ethyl and linear or branched alkyl groups containing three, four or five carbon atoms. In some embodiments, a cyclopentenyl group comprises at least one alkyl substituent, wherein the alkyl substituent is selected from C1 to C5 alkyls. In some embodiments, the alkyl substituent is selected from a group consisting of methyl, ethyl and linear or branched alkyl group comprising three, four or five carbon atoms. In some embodiments, the alkyl substituent is selected from a group consisting of methyl, ethyl, n-propyl, isopropyl, n-butyl, isobutyl, sec-butyl, tert-butyl, n-pentyl, 1,1-dimethylpropyl, 3-methylbutyl, 1-methylbutyl, 2,2-dimethylpropyl, 1-ethylpropyl, 1,2-dimethylpropyl and 2-methylbutyl. In some embodiments, the first metal precursor comprises two methylcyclopentadienyl ligands. In some embodiments, the first metal precursor comprises two ethylcyclopentadienyl ligands. In some embodiments, the first metal precursor comprises two n-propylcyclopentadienyl ligands. In some embodiments, the first metal precursor comprises two isopropylcyclopentadienyl ligands.

In some embodiments, the metal precursor is an Al precursor. In some embodiments, the Al precursor is selected from a group consisting of AlMe₃, AlEt₃, AlMe₂H, AlMe₂OⁱPr, AlMe₂(C₃H₆NMe₂), Al(OEt)₃, Al(OPr)₃, Al(O^{s}Bu)₃, Al(OⁱPr)₃, AlMe₂OⁱPr, Al(ⁱPrAMD)Et₂, Al(mmp)₃, Al(NMe₂)₃, Al(NEt₂)₃, Al(NEt₂)₂(C₃H₆NMe₂), Al(NⁱPr₂)₂(C₃H₆NMe₂), AlMe₂Cl, AlCl₃ and AlH₃N:(C₅H11)

In some embodiments, the metal precursor is an Y precursor. In some embodiments, the Y precursor is selected from a group consisting of Y(CpBu)₃, Y(CpEt)₃, Y(CpMe)₃, Y(DPDMG)₃, Y(EtCp)₂(ⁱPr₂AMD), Y(ⁱPr₂AMD)₃, Y(ⁱPrCp)₂(ⁱPr₂AMD), Y(ⁱPrCp)₃, Y(ⁱPrFMD)₃, Y(^{s}BuCp)₃, Y(^{t}Bu₂FMD)₃, Y(thd)₃ and YCp₃.

In some embodiments, the metal precursor is a Zr precursor. In some embodiments, the Zr precursor is selected from a group consisting of Zr(Cp)(^{t}BuDAD)(OⁱPr), Zr(Cp₂CMe₂)Me(OMe), Zr(Cp₂CMe₂)Me₂, Zr(CpEt)(NMe₂)₃, Zr(CpMe)(NMe₂)₃, Zr(CpMe)₂Me(OMe), Zr(CpMe)₂Me₂, Zr(CpMe)CHT, Zr(CpMe₂)₂Me(O^{t}Bu), Zr(dmae)₄, Zr(Me₅Cp)(TEA), Zr(MeAMD)₄, Zr(MeCp)(TMEA), Zr(NEt₂)₄, Zr(NEtMe)₂(guan-NEtMe)₂, Zr(NEtMe)₃(guan-NEtMe), Zr(NEtMe)₄, Zr(NMe₂)₄, Zr(OⁱPr)₂(dmae)₂, Zr(OⁱPr)₄, Zr(O^{t}Bu)₂(dmae)₂, Zr(O^{t}Bu)₄, Zr(thd)₄, Zr[N(SiMe₃)₂]₂Cl₂, ZrCl₄, ZrCp(NMe₂)₃, ZrCp₂Cl₂, ZrCp₂Me(OMe), ZrCp₂Me₂ and ZrI₄. “CHT” stands of cycloheptatriene, “TEA” stands for triethoanolaminate and “guan” for guanidinato.

In some embodiments, the metal precursor is a Hf precursor. In some embodiments, the Hf precursor is selected from a group consisting of Hf(BH₄)₄, Hf(Cp)(NMe₂)₃, Hf(Cp)(NMe₂)₃, Hf(Cp₂CMe₂)Me(OMe), Hf(Cp₂CMe₂)Me₂, Hf(CpMe)(NMe₂)₃, Hf(CpMe)₂(mmp)Me, Hf(CpMe)₂(OⁱPr)Me, Hf(CpMe)₂(OMe)Me, Hf(CpMe)₂Me₂, Hf(CpMe₂)(NMe₂)₃, Hf(dmap)₄, Hf(ⁱPrFMD)₂(NMe₂)₂, Hf(mmp)₄, Hf(mp)₄, Hf(NEt₂)₄, Hf(NEtMe)₂{η5:η1-Cp(CH₂)NMe}, Hf(NEtMe)₄, Hf(NMe₂)₂(guan-NMe₂)₂, Hf(NMe₂)₄, Hf(NO₃)₄, Hf(OⁱPr)₄, Hf(ONEt₂)₄, Hf(O^{t}Bu)(NEtMe)₃, Hf(O^{t}Bu)₂(mmp)₂, Hf(O^{t}Bu)₄, Hf(O^{t}Bu)₄, Hf[N(SiMe₃)₂]₂Cl₂, Hf{η₂-(ⁱPrN)₂CNEtMe}(NEtMe)₃, HfCl₄, HfCp(edpa)₃, HfCp₂Cl₂, HfCp₂Me₂, HfI₄. “mmp” stands for 1-methoxy-2-methyl-2-propanolate, and “mp” for 3-Methyl-3-pentoxide.

In some embodiments, the metal precursor is a Ga precursor. In some embodiments, the Ga precursor is selected from a group consisting of (GaMe₂NH₂)₃, Ga(acac)₃, Ga(CpMe₅), Ga(thd)₃, Ga₂(NMe₂)₆, GaEt₃, GaI₃, GaMe₂(OⁱPr), GaMe₂NH₂, GaMe₃, GaMe₃(CH₃OCH₂CH₂NH^{t}Bu).

In some embodiments, the metal precursor is a Ti precursor. In some embodiments, the Ti precursor is selected from a group consisting of Ti(Cp)CHT, Ti(CpMe)(OⁱPr)₃, Ti(CpMe5)(OMe)₃, Ti(EtCp)(NMe₂)₃, Ti(NEt₂)₄, Ti(NEtMe)₃(guan-NEtMe), Ti(NMe₂)₃(CpMe), Ti(NMe₂)₃(CpN), Ti(NMe₂)₃(dmap), Ti(NMe₂)₃(guan-NMe₂), Ti(NMe₂)₄, Ti(NMeEt)₄, Ti(OEt)₄, Ti(OⁱPr)₂(dmae)₂, Ti(OⁱPr)₂(NMe₂)₂, Ti(OⁱPr)₂(thd)₂, Ti(OⁱPr)₃(ⁱPr₂AMD), Ti(OⁱPr)₄, Ti(OMe)₄, Ti(O^{t}Bu)₄, Ti(trhd)₂(O(CMe₂Et)₂, TiCl₄, TiCp₂((ⁱPrN)₂C(NHⁱPr)), TiF₄, TiI₄.

In some embodiments, the metal precursor is a Ru precursor. In some embodiments, the Ru precursor is selected from a group consisting of Ru(CpEt)(dmopd), Ru(CpEt)₂, Ru(DMBD)(CO)₃, Ru(DMPD)₂, Ru(EBCHD), Ru(hd)(ipmp), Ru(thd)₂(cod), Ru(TMM)(CO)₃, RuO₄. “dmopd” stands for 2,4-dimethyloxopentadienyl and “dmbd” for 2,3-dimethylbutadiene and “dmpd” for 2,4-dimethylpentadienyl. EBCHD refers to a combination of ethylbenzene and 1,3-cyclohexadiene ligands. “hd” stands for hexadiene, “ipmp” for 1-isopropyl-4-methylbenzene, “cod” for cyclooctadiene and “TMM” for trimethylenemethane.

### Second Material Precursor

In some embodiments, the metal-containing material is selected from metal oxides and metal nitrides. In some embodiments, the second material precursor is selected from oxygen precursors and nitrogen precursors. When a metal oxide is deposited, the second material precursor is an oxygen precursor. Metal oxides may be used for various purposes, such as dielectric layers, etch stop layers, barriers to diffusion, and more recently, as threshold voltage shifting layers, in semiconductor devices. Selective deposition of metal oxides could allow utilizing the properties of metal oxide layers optimally, as the need for patterning and etching steps may be reduced. Thermal deposition methods may be preferred in metal oxide deposition over plasma-enhanced methods, due to better compatibility with sensitive materials.

In some embodiments, the second material precursor is an oxygen precursor. In some embodiments, the oxygen precursor is selected from a group consisting of ozone (O₃), molecular oxygen (O₂), oxygen atoms (O), an oxygen plasma, oxygen ions, oxygen radicals, oxygen excited species, water (H₂O), and hydrogen peroxide (H₂O₂). In some embodiments, the oxygen precursor is molecular oxygen (O₂). In some embodiments, the oxygen precursor is ozone. In some embodiments, the oxygen precursor is hydrogen peroxide. In some embodiments, the oxygen precursor is water. In some embodiments, the metal-containing material may comprise additional elements in addition to the metal and the oxygen or nitrogen. In some embodiments, the second material precursor is used to introduce an additional element into the metal-containing material. For example, the metal-containing material may comprise a metal, silicon and oxygen. Such material may be deposited by contacting the substrate with a metal precursor, and thereafter contacting it with an oxygen precursor containing another element, such as silicon. In some embodiments, the oxygen precursor may be a siloxane, whereby the metal-containing material comprises silicon. For example, using an aluminum precursor, and a siloxane as an oxygen precursor, AlSiOx (aluminum silicon oxide) may be deposited. In such a case, the metal-containing material will contain significant amounts of all three elements.

In some embodiment, the oxygen precursor comprises a hydroxyl group. In some embodiments, a one or more hydroxyl groups is substantially the only reactive group in the oxygen precursor. In some embodiments, the oxygen precursor is an alcohol. In some embodiments, the alcohol is substantially the only oxygen source in the deposition process.

In some embodiments, the alcohol is a primary alcohol. In some embodiments, the alcohol is a secondary alcohol. In some embodiments, the alcohol is a tertiary alcohol. In some embodiments, the oxygen precursor is a secondary or tertiary alcohol. In some embodiments, the alcohol comprises one carbon atom. In some embodiments, the alcohol comprises two carbon atoms. In some embodiments, the alcohol comprises three carbon atoms. In some embodiments, the alcohol comprises four carbon atoms. In some embodiments, the alcohol comprises five carbon atoms. In some embodiments, the alcohol comprises six carbon atoms.

In some embodiments, the alcohol comprises one hydroxyl group. In some embodiments, the alcohol comprises two hydroxyl groups. In some embodiments, the alcohol comprises at least two hydroxyl groups. In some embodiments, the alcohol comprises three hydroxyl groups. In some embodiments, the alcohol comprises at least three hydroxyl groups. In some embodiments, the alcohol comprises four hydroxyl groups. In some embodiments, the alcohol comprises at least four hydroxyl groups. In some embodiments, the alcohol comprises five hydroxyl groups. In some embodiments, the alcohol comprises at least five hydroxyl groups.

In some embodiments in which the oxygen precursor comprises at least two hydroxyl groups, each hydroxyl group is bonded to a different carbon atom. In some embodiments, two hydroxyl groups are bonded to one carbon atom. In some embodiments, at least two hydroxyl groups are bonded to one carbon atom. In some embodiments, the alcohol comprises two carbon atoms being bonded to two hydroxyl groups. In some embodiments, the alcohol comprises at least two carbon atoms being bonded to two hydroxyl groups. In some embodiments, the alcohol comprises three carbon atoms being bonded to two hydroxyl groups. In some embodiments, the alcohol comprises at least three carbon atoms being bonded to two hydroxyl groups. In some embodiments, the oxygen precursor does not comprise carboxyl groups. In some embodiments, the only oxygen atom(s) in the oxygen precursor are in the hydroxyl groups. In some embodiments, the oxygen precursor contains only carbon and hydrogen in addition to the oxygen in the hydroxyl group(s). In some embodiments, and additional oxygen precursor may be used for tuning the deposition process. For example, a high-reactivity oxygen precursor, such as ozone, or oxygen plasma, may be used at the end of the process to ascertain sufficient conversion of the first precursor and the optional second metal precursor into oxide material.

In some embodiments, the oxygen precursor is selected from a group consisting of methanol, ethanol, propan-1-ol, propan-2-ol, butan-1-ol, butan-2-ol, pentan-1-ol, iso-butanol, tert-butanol, pentan-2-ol, pentan-3-ol, ethane-1,2-diol, propane-1,2-diol, propane-1,2,3-triol, butane-1,2-diol, butane-2,3-diol, butane-1,3-diol, butane-1,4-diol, butane-1,2,3-triol, butane-1,2,3,4-tetraol, pentane-1,2-diol, pentane-1,3-diol, pentane-1,4-diol, pentane-1,5-diol, pentane-2,3-diol, pentane-2,4-diol, pentane-1,2,3-triol, pentane-1,2,4-triol, pentane-1,2,5-triol, pentane-2,3,4-triol, pentane-1,2,3,4-tetraol, pentane-1,2,3,5-tetraol, pentane-1,2,4,5-tetraol.

Using an alcohol as an oxygen precursor may have the benefit of avoiding oxidation of metal surfaces of the substrate. Additionally, the rate of deposition when using an alcohol as an oxygen precursor may be lower compared to conventional, and more oxidizing, oxygen precursors. This may be beneficial in some applications, in which very careful control of oxide material layer thickness, or very thin oxide material layer is targeted.

When a metal nitride is deposited, the second material precursor is a nitrogen precursor. In some embodiments, the second material precursor is a nitrogen precursor. The term nitrogen precursor can refer to a gas or a material that can become gaseous and that can be represented by a chemical formula that includes nitrogen. In some cases, the chemical formula includes nitrogen and hydrogen. In some cases, the nitrogen precursor does not include diatomic nitrogen. The nitrogen precursor may be selected from one or more of ammonia (NH3), hydrazine (N2H4), and other compounds comprising or consisting of nitrogen and hydrogen. For example a mixture of nitrogen gas and hydrogen gas may be used. In an embodiment, the nitrogen precursor does not include diatomic nitrogen, i.e. the nitrogen precursor is a non-diatomic precursor.

In some embodiments, the nitrogen precursor is selected from a group consisting of molecular nitrogen (N₂), ammonia (NH₃), hydrazine (NH₂NH₂) and a hydrazine derivative, such as tert-butylhydrazine.

In some embodiments, the nitrogen precursor comprises ammonia. In some embodiments, the nitrogen precursor consists essentially of, or consists of ammonia. In some embodiments the nitrogen precursor comprises an alkylamine. In some embodiments the nitrogen precursor consists essentially of or consists of an alkylamine. Examples of alkylamines include dimethylamine, n-butylamine and tert-butylamine.

In some embodiments, the nitrogen precursor comprises hydrazine. In some embodiments, the nitrogen precursor consists essentially of, or consists of hydrazine. In some embodiments the nitrogen precursor comprises hydrazine substituted by one or more alkyl or aryl substituents. In some embodiments the nitrogen precursor consists essentially of, or consists of hydrazine substituted by one or more alkyl or aryl substituents. In some embodiments, the hydrazine derivative comprises an alkyl-hydrazine including at least one of: tert-butylhydrazine (C₄H₉N₂H₃), methylhydrazine (CH₃NHNH₂), 1,1-dimethylhydrazine ((CH₃)₂NNH₂), 1,2-dimethylhydrazine (CH₃) NHNH(CH₃), ethylhydrazine, 1,1-diethylhydrazine, 1-ethyl-1-methylhydrazine, isopropylhydrazine, phenylhydrazine, 1,1-diphenylhydrazine, 1,2-diphenylhydrazine, N-aminopiperidine, N-aminopyrrole, N-aminopyrrolidine, N-methyl-N-phenylhydrazine, 1-amino-1,2,3,4-tetrahydroquinoline, N-aminopiperazine, 1,1-dibenzylhydrazine, 1,2-dibenzylhydrazine, 1-ethyl-1-phenylhydrazine, 1-aminoazepane, 1-methyl-1-(m-tolyl) hydrazine, 1-ethyl-1-(p-tolyl) hydrazine, 1-aminoimidazole, 1-amino-2,6-dimethylpiperidine, N-aminoaziridine, or azo-tert-butane.

In some embodiments, the nitrogen precursor does not contain carbon, i.e. it is carbon-free. In some embodiments, the nitrogen precursor does not contain silicon, i.e. it is silicon-free. Depending on the selected nitrogen precursor, it may be liquid or gaseous in the precursor vessel upon vaporization. Also solid precursors may be used.

In some embodiments, the nitrogen precursor comprises ammonium hydroxide (NH₄OH). Without limiting the current disclosure to any specific theory, the use of ammonium hydroxide may lead into the incorporation of oxygen into the deposited material. This may have advantages in some applications of the method.

The methods according to the current disclosure may be used for forming semiconductor structures, such as trench contacts, and for manufacturing semiconductor devices comprising said structures.

### DRAWINGS

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative deposition rates of different materials indicated in the drawings may deviate from the experimental results, the specifics of which may vary according to process conditions. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

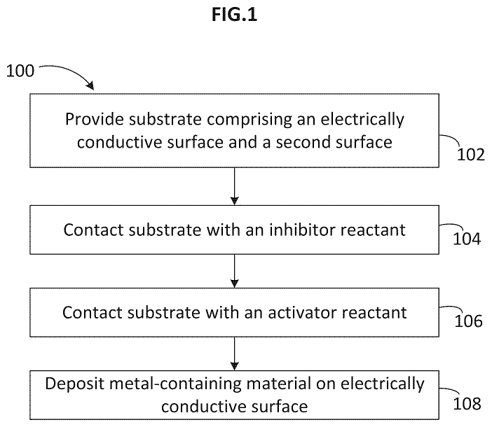

FIG. 1 is a block diagram of an exemplary embodiment of a method 100 according to the current disclosure. First, a substrate is provided. In some embodiments, the substrate is provided in a reaction chamber, such as a first reaction chamber, at stage 102. The substrate comprises a first electrically conductive surface and a second surface as described in the current disclosure. For example, the first surface may be an elemental metal surface, such as a copper (Cu), cobalt (Co), molybdenum (Mo) or a tungsten (W) surface. Alternatively, the first surface may be a conductive metal nitride surface, such as a titanium nitride (TiN), tungsten nitride (WN) or a molybdenum nitride (MoN) surface. The second surface may be a dielectric surface. In some embodiments, the second surface comprises silicon. For example, the second surface may be a silicon dioxide (SiO₂), silicon nitride (SiN) or a silicon oxynitride (SiOC) surface. The substrate may be heated at stage 102 prior to contacting the substrate with an inhibitor reactant 104 according to the current disclosure.

At stage 104, the substrate is contacted with an inhibitor reactant as disclosed herein. The inhibitor reactant passivates the second surface, allowing the further reactions by the metal precursor and the second material precursor with the electrically conductive surface. However, before the metal-containing material is deposited on the electrically conductive surface, the substrate is contacted with an activator reactant as disclosed herein at stage 106.

At stage 108, metal-containing material is deposited on the electrically conductive surface by a cyclic deposition process. The deposition may take place by an ALD process. Without limiting the generality of the disclosure, an ALD-type process may be advantageous for selective deposition according to the current disclosure, as the substantially monolayer-growth provides improved control of the growth over other types of vapor deposition processes.

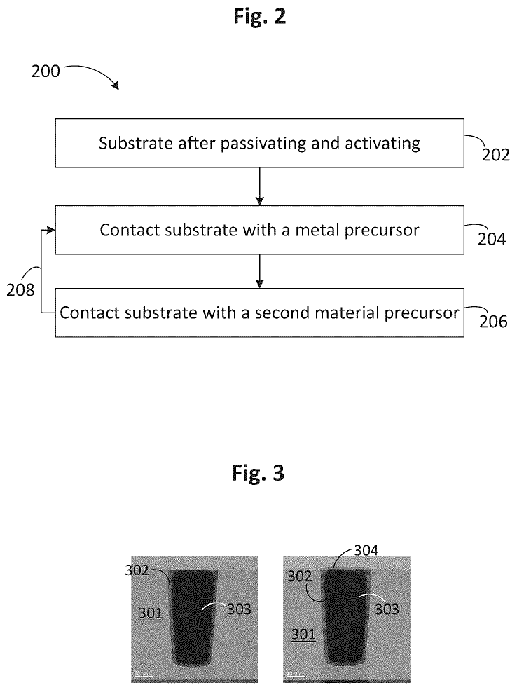

FIG. 2 describes the cyclic deposition process of the metal-containing material 200 according to the current disclosure in more detail. At stage 202, the substrate after passivating and activating (i.e. after stage 106 of FIG. 1) is provided. The substrate is brought into a deposition chamber, which, in some embodiments, is a different reaction chamber than the one in which the activation of stage 106 of FIG. 1 was performed. The substrate may be brought into a suitable temperature for deposition, which may be the same or different as in the preceding stage. In some embodiments, the deposition 200 takes place at a temperature from about 150° C. to about 350° C. For example, a deposition temperature of about 200° C., 250° C., 275° C. 300° C. or 325° C. may be used. The deposition temperature and other deposition conditions are selected based on the precursors used in the deposition process.

At stage 204, the substrate is contacted with a metal precursor, and at stage 206 with a second material precursor. As disclosed herein, the second material precursor may be an oxygen precursor for depositing metal oxides, or a nitrogen precursor for depositing metal nitrides. Contacting the substrate with the metal precursor 204 and the second material precursor 206 may define a deposition cycle, which may be repeated, as indicated by the loop 208. The deposition cycle may be repeated as many times as necessary to deposit a desired amount of metal-containing material on the conductive surface. In some embodiments, the deposition cycle 208 is performed from about 3 to 500 times, or from about 5 to about 200 times, or from about 5 to about 100 times, or from about 5 to about 70 times, or from about 5 to about 50 times. In some embodiments, the selectivity may be lost after a given number of deposition cycles. Therefore, the method may comprise intermitted etch-back, or renewal of the passivation and/or activation to retain sufficient degree of selectivity.

In preliminary tests of the invention, a substrate comprising metallic W or TiN as the electrically conductive surface and SiO₂ as the second surface was used to grow aluminum oxide as the metal-containing surface. The substrate was first contacted with an inhibitor reactant at a temperature of 200° C. for 25 seconds. The inhibitor reactant in the test was trimethylsilyldimethylamine. Contacting the substrate with the inhibitor reactant was followed by a purge.

After the substrate was contacted with the inhibitor reactant, the temperature was raised to 300° C., and the substrate was contacted with tris(tert-pentoxy)silanol as the activator reactant for 50 to 500 seconds, and aluminum oxide was deposited on the electrically conductive surface by methods known in the art. The tests indicated that the selectivity window was dramatically increased by using the activator reactant, from about 10 reaction cycles to between 30 and 40 cycles. The increase in the selectivity window was mostly attributable to the reduction in growth delay of the metal-containing material on the electrically conductive surface.

FIG. 3 is an electron micrograph of a metal-containing layer deposited according to the current disclosure. In the left panel, a trench in silicon dioxide material 301 filled with elemental tungsten (W) 303 is indicated. The trench comprises a liner 302 of titanium nitride. In the right panel, aluminum oxide 304 is deposited on the tungsten 303 as well on the TiN 302 surface. FIG. 3 illustrates the clear selectivity of the deposition on the W and TiN surfaces relative to the adjacent SiO₂ surface. About 20 to 30 Å of aluminum oxide has been deposited on W and TiN, relative to non-detectable deposition on SiO₂. Although in the embodiment of FIG. 3, the metal-containing material is deposited on a planar surface, the methods are applicable to surfaces that are not on the same plane, or do not have the same orientation (i.e. not all horizontal relative to the overall substrate surface). The current methods may be advantageous over methods known in the art in that the

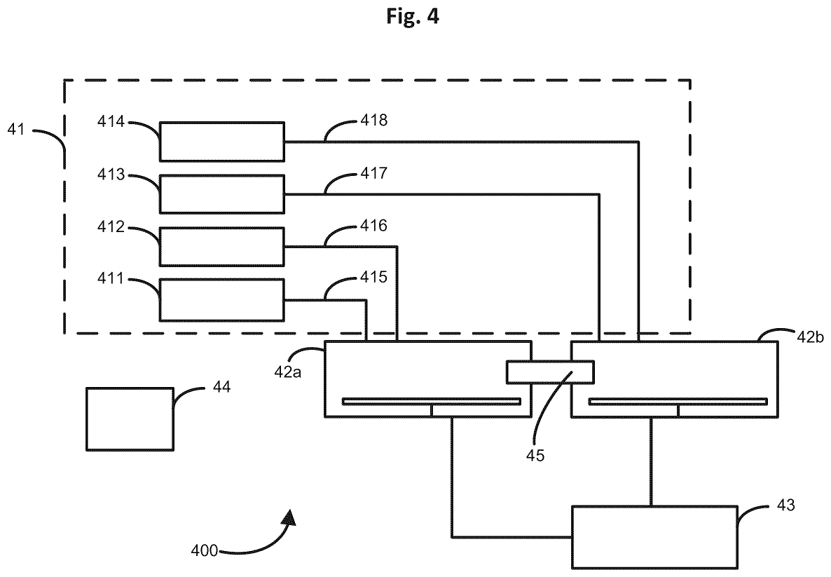

FIG. 4 is a schematic drawing of an embodiment of a substrate processing assembly 400 according to the current disclosure. A substrate processing assembly 400 according to the current disclosure comprises a first reaction chamber 42a and a second reaction chamber 42b, each constructed and arranged to hold a substrate comprising an electrically conductive surface and a second surface. The substrate processing assembly 400 further comprises a substrate transfer arrangement 45 for moving the substrate from first reaction chamber 42a to the second reaction chamber 42b, a first reactant vessel 411 constructed and arranged to hold an inhibitor reactant comprising silicon, a second reactant vessel 412 constructed and arranged to hold an activator reactant comprising a silanol, a third reactant vessel 413 constructed and arranged to hold a metal precursor and a fourth reactant vessel 414 constructed and arranged to hold a second material precursor. The substrate processing assembly 400 also comprises a precursor injector system 41 constructed and arranged to provide the inhibitor reactant and the activator reactant from the first reactant vessel 411 and the second reactant vessel 412, respectively, to the first reaction chamber 42a in a vapor phase; and the metal precursor and the second material precursor from the third reactant vessel 413 and the fourth reactant vessel 414, respectively, to the second reaction chamber 42b in a vapor phase. In some embodiments, the substrate processing assembly 400 comprises a controller 44 configured to control the flow of the inhibitor reactant and the activator reactant into the first reaction chamber 42a, and the flow of the metal precursor and second material precursor into the second reaction chamber 42b for executing the method according to the current disclosure, thereby selectively depositing a metal-containing material on the electrically conductive surface of the substrate. Controller 44 includes electronic circuitry and software to selectively operate valves, manifolds, heaters, pumps and other components included in the substrate processing assembly 400. Such circuitry and components operate to introduce precursors, reactants and other gases from the respective sources. Controller 44 can control timing of gas pulse sequences, temperature of the substrate and/or pressure within the reaction chambers 42a, 42b, and various other operations to provide proper operation of the processing assembly 400. Controller 44 can include control software to electrically or pneumatically control valves to control flow of precursors, reactants and other gases into and out of the reaction chambers42a, 42b. Controller 44 can include modules such as a software or hardware component, which performs certain tasks

FIG. 4 also indicates an exhaust source 43 that can include one or more vacuum pumps. The exhaust source is in fluid connection to both the first reaction chamber 42a and the second reaction chamber 42b.

Other configurations of processing assembly 400 are possible, including different numbers and kinds of reactant vessels. For example, instead of two separate reaction chambers 42a, 42b, the substrate processing assembly may comprise more than one, such as two or four, deposition stations in a single reaction chamber. Such a multi-station configuration may have advantages if, for example, blocking, passivation and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chambers 42a, 42b. Further, as a schematic representation of a substrate processing assembly 400, many components have been omitted for simplicity of illustration, and such components may include, for example, various valves, manifolds, purifiers, heaters, containers, vents, and/or bypasses.

During operation of processing assembly 400, substrates, such as semiconductor wafers (not illustrated), are transferred from, e.g., a substrate handling system to the first reaction chamber 42a for passivation and activations. Thereafter, they will be moved by the substrate transfer arrangement 45 to the second reaction chamber 42b for selective deposition. Once substrate(s) are transferred to the first or second reaction chamber 42a, 42b, one or more gases from gas sources, such as precursors, reactants, carrier gases, and/or purge gases, are introduced into the reaction chamber in question.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A selective deposition method for depositing metal-containing material on an electrically conductive surface of a substrate relative to a second surface of the substrate; the method comprising
providing the substrate comprising the electrically conductive surface and the second surface;
contacting the substrate with an inhibitor reactant comprising silicon to passivate the second surface;
contacting the substrate with an activator reactant comprising a silicon atom and a hydroxyl group to activate the electrically conductive surface; and
depositing the metal-containing material on the electrically conductive surface by a cyclic deposition process.

2. The method of claim 1, wherein the metal-containing material comprises at least one of Al, Y, Zr, Hf, La, Ga, Ti and Ru.

3. The method of claim 1, wherein the metal-containing material is selected from metal oxides and metal nitrides.

4. The method of claim 1, wherein the metal-containing material is aluminum oxide, yttrium oxide or a combination thereof.

5. The method of claim 1, wherein the metal-containing material is deposited as a layer.

6. The method of claim 1, wherein the electrically conductive surface is selected from elemental metals and conductive metal nitrides.

7. The method of claim 1, wherein the electrically conductive surface is an elemental metal surface selected from Cu, Co, W, Ru, Al, Ta and Mo.

8. The method of claim 1, wherein the electrically conductive surface is selected from TaN, TiN, WN, MoN.

9. The method of claim 1, wherein the second surface is a silicon-comprising surface.

10. The method of claim 1, wherein the inhibitor reactant comprises a Si—N bond or a Si-halogen bond.

11. The method of claim 1, wherein the inhibitor reactant has a formula SiR3NR′2, wherein each R is independently selected from C1 to C5 alkyls and alkoxides, and each R′ is independently selected from C1 to C7 alkyls.

12. The method of claim 1, wherein the inhibitor reactant is selected from a group consisting of N-(trimethylsilyl)dimethylamine, 1-(triisopropylsilyl)pyrrole, 1-(trimethylsilyl)imidazole, 1,1,1-trimethoxy-N,N-dimethylsilanamine, bis(dimethylamino)dimethylsilane, bis(dimethylamino)diethylsilane and chlorotrimethylsilane.

13. The method of claim 1, wherein the activator reactant comprises a silicon-hydroxyl (Si—OH) bond.

14. The method of claim 1, wherein the activator reactant is a silanol comprising at least one alkoxy substituent attached to a silanol silicon atom.

15. The method of claim 14, wherein the activator reactant is selected from a group consisting of trimethoxysilanol, triethoxysilanol, tripropoxysilanol, tris(sec-butoxy)silanol, tris(tert-butoxy)silanol and tris(tert-pentoxy)silanol.

16. The method of claim 1, wherein the metal-containing material is deposited by an ALD process.

17. The method of claim 1, wherein the cyclic deposition process for depositing a metal-containing material comprises contacting the substrate with a metal precursor and a second material precursor alternatively and sequentially.

18. The method of claim 17, wherein the metal precursor comprises a ligand selected from alkyl ligands, alkoxy ligands, amino ligand, amidinato ligands, cyclopentadienyl ligands, β-diketonate ligands, halogen ligands and guanidinato ligands.

19. The method of claim 18, wherein the metal precursor is a heteroleptic precursor.

20. The method of claim 18, wherein the second material precursor is selected from oxygen precursors and nitrogen precursors.

21. A substrate processing assembly, comprising
a first reaction chamber and a second reaction chamber, each constructed and arranged to hold a substrate comprising an electrically conductive surface and a second surface;
a substrate transfer arrangement for moving the substrate from first reaction chamber to the second reaction chamber;
a first reactant vessel constructed and arranged to hold an inhibitor reactant comprising silicon;
a second reactant vessel constructed and arranged to hold an activator reactant comprising a silanol;
a third reactant vessel constructed and arranged to hold a metal precursor;
a fourth reactant vessel constructed and arranged to hold a second material precursor;
a precursor injector system constructed and arranged to provide
the inhibitor reactant and the activator reactant from the first reactant vessel and the second reactant vessel, respectively, to the first reaction chamber in a vapor phase; and
the metal precursor and the second material precursor from the third reactant vessel and the fourth reactant vessel, respectively, to the second reaction chamber in a vapor phase; and
a controller configured to control flow of the inhibitor reactant and the activator reactant into the first reaction chamber, and flow of the metal precursor and second material precursor into the second reaction chamber for executing a method comprising
providing the substrate comprising the electrically conductive surface and the second surface;
contacting the substrate with an inhibitor reactant comprising silicon to passivate the second surface;
contacting the substrate with an activator reactant comprising a silicon atom and a hydroxyl group to activate the electrically conductive surface; and
depositing a metal-containing material on the electrically conductive surface by a cyclic deposition process.
